(19) United States
(12) Patent Application Publication
(10) Pub. No.: US 2008/0245352 A1
(43) Pub. Date: Oct. 9, 2008

(54) THERMO-ELECTRIC GENERATOR FOR USE WITH A STOVE

(75) Inventors: Anthony Solecki, Owen Sound (CA); Michael Tettenborn, Kemble (CA); Kelly McNamee, Toronto (CA); Larry Whittle, Sauble Beach (CA)

Correspondence Address: MARKS & CLERK, P.O. BOX 957, STATION B, OTTAWA, ON, K1P 5S7, CA

(73) Assignee: CAFRAMO LIMITED, Wiarton (CA)

(21) Appl. No.: 12/046,627

(22) Filed: Mar. 12, 2008

Related U.S. Application Data
(60) Provisional application No. 60/894,719, filed on Mar. 14, 2007.

(51) Int. Cl. F24C 1/00; H01L 35/00

(52) U.S. Cl. 126/58; 136/205

(57) ABSTRACT

Disclosed is in combination, a stove and a thermoelectric generator, wherein the stove has a heating chamber and the generator has a hot side plate positioned in use within the heating chamber in a direct path of the heat therefrom. The generator may be incorporated with a door of the stove. Preferably, the generator has a cold side plate positioned in use to be exposed to ambient air close to the ground. The cold side plate may comprise cooling fins and the cooling fins may be positioned to be exposed to ambient air close to the ground. The generator may further comprise a protective mechanism to protect the generator from overheating, such as a grillwork guard or a shutter that closes to block the direct heat from the generator mechanism. The stove may be a wood stove or a coal stove. Generated power can be used to power cooling fans, charge an energy storage device and/or power external devices such as lights, fans or radios for example.

### CROSS-REFERENCE TO RELATED APPLICATION

This application claims the benefit of U.S. Provisional Application No. 60/894,719 filed Mar. 14, 2007, incorporated by reference herein.

### FIELD OF THE INVENTION

The present invention relates to thermoelectric generators. More specifically, the present invention relates to a stove having a thermoelectric generator.

### BACKGROUND OF THE INVENTION

Use of wood and coal stoves is surprisingly common. These stoves are used by many people around the world, including remote locations throughout North America. Many of the people who rely on wood/coal stoves do so because they do not have ready access to electricity.

Thermo-electric generators for wood and coal stoves are known. The generators use heat from the stove and convert it to electric power which can be used to power external loads. Heat passes through a hot side plate of the generator to a cold side plate and a thermoelectric module uses the temperature difference between the hot side plate and cold side plate to convert the heat to electric power. Therefore, the higher the temperature difference between the hot side plate and cold side plate, the more electric power is generated

However, the heat from a wood or coal stove varies substantially. Further, the generators are typically located either on top of the stove or in the stovepipe, which does not provide the most efficient use of the heat from the stove. One common embodiment attaches the generator to the chimney of the wood stove (see http://www.hi-z.com/websit13.htm). In another embodiment, the generator is free-standing, and is placed on the wood stove (see http//hi-z.com/websit10.htm).

Each of these approaches has drawbacks. In the first case, a modification to the chimney is required, specifically to draw heat from the flue gases. The chimney of a modem wood stove is carefully designed to optimize the combustion of flue cases, and to maintain the heat of the flue gases so that the stove draws properly, and to prevent buildup of combustion byproducts (creosote) on the inside of the chimney. Any modification to the chimney will reduce the efficiency of the stove, create more pollution, and create a safety hazard with the buildup of creosote.

In the second case, the generator is placed on the surface of the stove. The placement of the generator directly over the fire causes risk of failure of the generator if the hottest part of the combustion is directly below the generator. Another drawback is that the stove top insulates the generator from the fire, so that this arrangement may also result in the heat being too low. In some stoves, there is an internal insulating plate or baffle that is designed to prevent the full heat from reaching the top surface.

In both cases, the ambient air used for cooling is drawn from near the stove top, where the air is warmed by the stove, and is not the coldest air in the room because of normal stratification where the warm air in a room rises and the cool air falls.

In Canadian Patent Application 2,470,739, the thermoelectric module is used with a fireplace and must be incorporated right within the original structure of the fireplace.

### SUMMARY OF THE INVENTION

A thermo-electric generator for a wood or coal stove is disclosed. According to teachings of this invention, the hot side plate of the generator is in a direct path of the heat from the stove. In this way, heat from the stove is more efficiently harnessed by the generator, resulting in more efficient electricity conversion. Preferably, the cold side plate is situated to be exposed to the ambient air close to the ground, which is typically cooler thus providing for a larger temperature gradient.

In one embodiment, the generator is incorporated within the door of the wood stove. The door comprising the generator can be installed on any typical wood/coal stove. The installed door then positions the hot side plate of the generator in a direct path of the heat. The door may be interchangeable with the standard door, where the standard door has a heatproof transparent window to observe the fire, and the generator door has no window or a smaller window.

The generator may also comprise cooling fins on the cold side plate, optional cooling fans, and electric controls combined with the appropriate fasteners and wiring. An optional guard can be placed on the exterior of the hot side plate on the side exposed to the heat. This may serve to protect the hot side plate from the direct heat. Preferably, the guard is a steel wire log guard.

In another embodiment, a bimetal operated mechanism can be used to protect the module from excess heat. When the stove surface is too hot, the bimetal strip forms a curve that lifts the assembly away from the stove surface, pressing against the force of the compression springs. When the stove surface is cooler, the bimetal strip returns to its normal, flat profile, lying within a slot provided in the lower surface of the pad.

The modules can be used in a side by side arrangement for multiple module use in a generator. Alternatively, a ‘floating’ arrangement where each module is attached to its own hot side pad and cold side pad, forming a module assembly can be used. The floating pad approach allows the module to more closely and evenly absorb heat from the uneven stove surface.

Alternatively, the floating pad has also been found to be useful in the construction of a stove top generator. In either embodiment, (door mounted generator or stove-top generator) use of the floating pad adds an additional benefit with respect to field service, since separate pads for each module provide for much easier replacement of failed modules, as the failed assembly can be easily removed without affecting the other modules.

Electric devices may be run directly from the generator, for example lights, circulating fans, radios, or computers; devices may be charged by the generator, for example cameras, cell phones, GPS or computers, or the energy may be stored in a battery.

Embodiments of the invention in accordance with these teachings have some of the following features:
a. The generator has direct access to the heat from the fire.
b. There is no alteration to the original structure of the wood stove.
c. The generator is near to floor level, so that the ambient air that is used for cooling is cooler.
d. There is no alteration to the chimney.
e. The user may use the standard door in most cases, and switch to the generator door only when needed.

Other aspects and advantages of embodiments of the invention will be readily apparent to those ordinarily skilled in the art upon a review of the following description.

### BRIEF DESCRIPTION OF THE DRAWINGS

Embodiments of the invention will now be described in conjunction with the accompanying drawings, wherein:

FIG. 1 illustrates a thermoelectric module mounted to a door of a stove in accordance with the teachings of this invention;

FIG. 2 illustrates a wood stove incorporating a thermoelectric generator of FIG. 1 in an exemplary embodiment in accordance with the teachings of this invention;

FIG. 3 illustrates a cut away of the stove of FIG. 2;

FIG. 4 illustrates a front view of the outside of the stove of FIG. 2;

FIG. 5 illustrates an embodiment of a bimetal operated mechanism that can be used to protect the thermoelectric module of the thermoelectric generator of FIG. 1 from excess heat;

FIG. 6 illustrates the bimetal operated mechanism of FIG. 5 when the stove surface is cooler;

FIG. 7 shows a traditional arrangement for multiple module use in a generator;

FIG. 8 shows a floating arrangement for multiple module use in a generator;

FIG. 9 illustrates a top level circuit diagram of the module circuit;

FIG. 10 illustrates a floating arrangement useful with stovetop generators;

FIG. 11 is a close up view of the float pads illustrating the pin through eyes on the float pad;

FIG. 12 illustrates assembly of the float pads of FIG. 11;

FIGS. 13 and 14 illustrate a stovetop generator with float pads of FIG. 11; and

FIG. 15 illustrates a complete assembly of a stovetop generator with float pads of FIG. 11.

This invention will now be described in detail with respect to certain specific representative embodiments thereof, the materials, apparatus and process steps being understood as examples that are intended to be illustrative only. In particular, the invention is not intended to be limited to the methods, materials, conditions, process parameters, apparatus and the like specifically recited herein.

### DETAILED DESCRIPTION OF THE DISCLOSED EMBODIMENTS

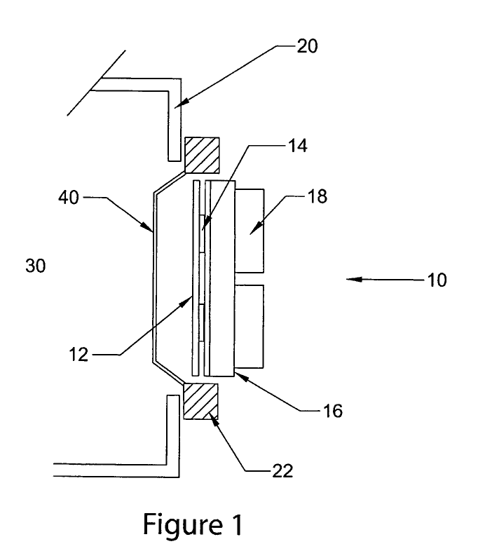

Referring to FIG. 1, there is illustrated a top level view of a thermoelectric (TE) generator 10. The generator 10 comprises a hot-side plate 12, thermoelectric modules 14, cold-side plate 16 with cooling fins (not seen in FIG. 1), optional cooling fans 18, and electric controls (not shown); combined with the appropriate fasteners and wiring (not shown). The general operation of a thermoelectric module is provided. A hot side plate 12 is heated from a heat source, such as a wood stove. A cold side plate 16 is cooled by ambient air. Thermo-electric modules 14 sandwiched between the hot side plate 12 and cold side plate 16 use the temperature difference to generate electric power.

Thermoelectric modules are widely available. Most are designed to create a temperature differential for cooling purposes, for refrigerators. TE modules for power generation use the same basic principles, but are designed to withstand higher temperatures on the hot side so that higher temperature difference can be achieved. The higher the temperature a module can withstand, the more useful it is in this application. One skilled in the art will understand the operation of a TE generator.

Embodiments of the invention will be described with reference to a wood stove, but one skilled in the art will appreciate that the teachings can be equally useful for other types of stoves such as coal stoves.

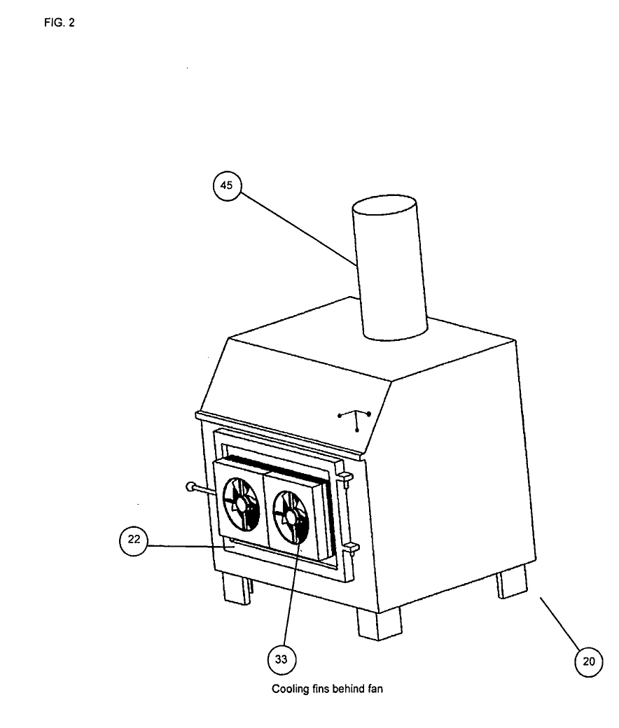

Referring to FIG. 2, there is illustrated a wood stove 20 incorporating a TE generator 10 in accordance with the teachings of this invention. In this exemplary embodiment, the thermo-electric generator is mounted to the door 22 of the wood stove 20. Any stove that has a door that is opened to add fuel would apply, such as a coal stove. The door 22 can replace the door of any standard wood or coal stove such that any existing stove can be retrofitted. In other embodiments, other walls or surfaces of the stove could be replaced with a wall or surface incorporating a thermoelectric generator. In this way, there is no alteration to the chimney 45.

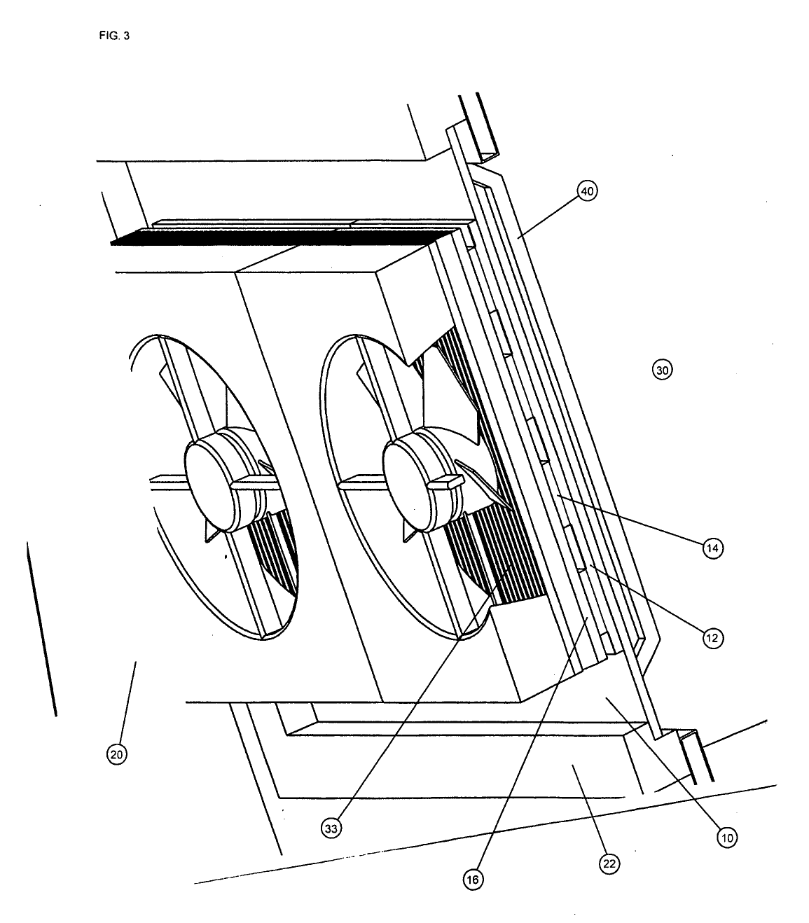

As seen in FIG. 3, the hot side plate 12 of the thermoelectric generator 10 is positioned within the heat chamber 30 of the stove 20 itself. In this embodiment, when the door 22 including the generator 10 is mounted to the stove 20 and closed, the hot side plate 12 in placed in a direct path of the heat produced by the stove 20. In this way, the generator 10 has direct access to the heat from the fire.

The cold side plate 16 is positioned to be exposed to the ambient room temperature. Preferably the generator 10 is mounted to the stove 20 such that the cold side plate 16 is relative low to the ground, where the ambient air is coolest thus generating a higher temperature gradient. The cold side plate 16 includes cooling fins 33. Vertical fins will enhance the airflow through natural convection.

Thermo-electric modules 14 are sandwiched between the hot 12 and cold 16 side plates to convert the thermal energy from the temperature gradient into electrical energy. Such thermo-electric modules 14 are known in the art. Preferably, the module used is a 35 mm module. Larger, more powerful modules are available, however such modules are harder to manufacture, meaning that for a given power output the cost to manufacture would be higher. For example, four 35 mm modules can be used to create a generating surface of 70 mm×70 mm with a cost four times the cost of one module. The manufacturing cost of a single module 70 mm×70 mm would be ten times the cost of a single module. Choosing the right size module will optimize the cost. However, the invention in accordance with these teachings will work with any size module, as one skilled in the art will appreciate.

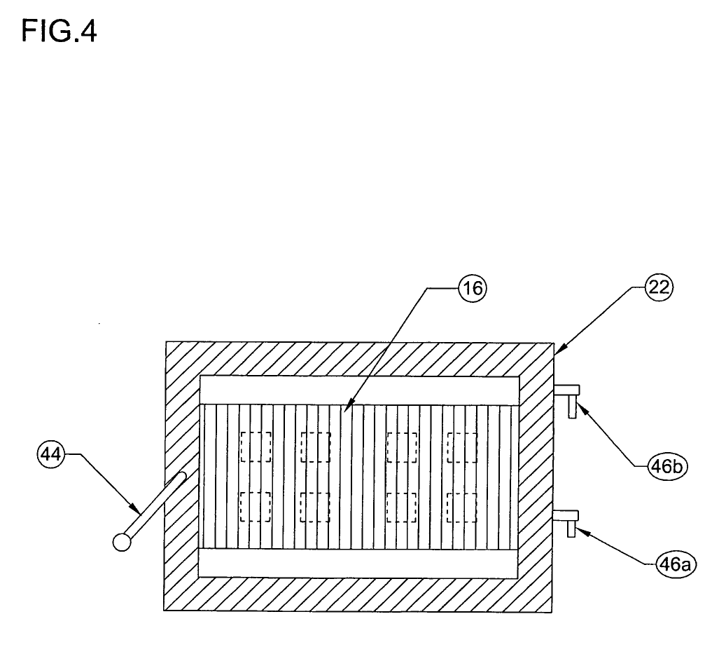

Referring to FIG. 4, in this embodiment, the door 22 may be interchangeable with the standard door, where the standard door has a heatproof transparent window to observe the fire, and the generator door has no window or a smaller window. In this way there is no alteration to the original structure of the stove 20. Further, the user may use the standard door in most cases, and switch to the generator door only when needed. The door 22 will include a door handle 44 and hinge pins 46a and 46b to facilitate ease of replacement of a standard door.

The cooling fans 18 are preferably mounted such that the fan intake is exposed to the cooler ambient air closer to the floor.

The wiring is standard wiring for a thermoelectric generator that one skilled in the art will be familiar with.

A mechanism to protect the generator 10 from overheating may be included. Overheating may come from an overly hot fire, or from firewood resting on the internal hot-side plate. One form of protection would be a grillwork guard 40 to prevent burning wood from resting directly on the generator mechanism.

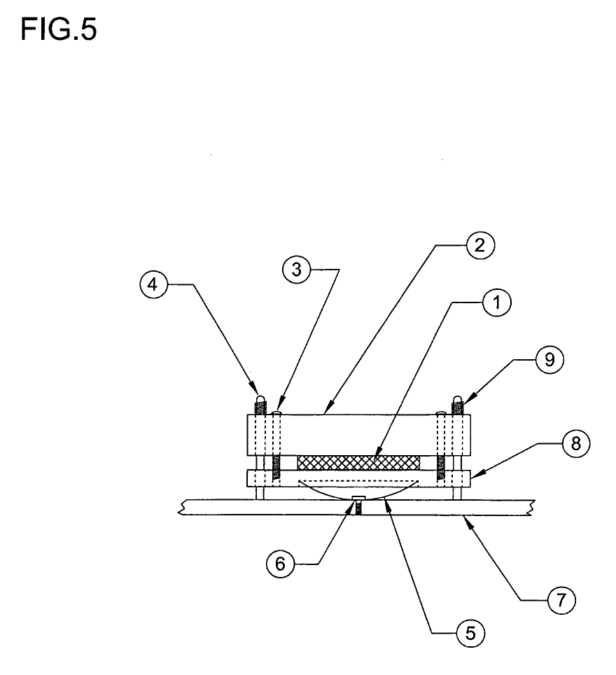

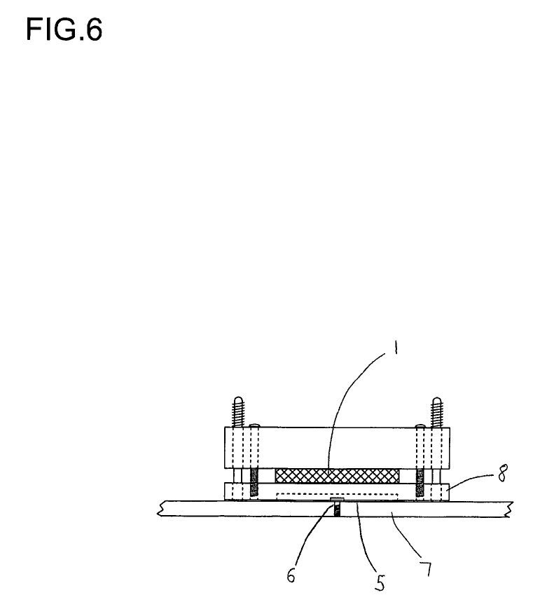

Another form of protection may be a lifter that forces the generator assembly away from the heat to interrupt the transfer of heat by conduction and convection. FIG. 5 shows an embodiment of a bimetal lifter mechanism where a bimetal strip bends in response to the heat from the stove. The introduction of ambient air into the gap between the stove surface and the hot side pad will further reduce the temperature of the hot side pad. The cooling air may be moved by convection, or by fan power. The form of the hot side pad may include heat transfer fins to enhance the effect of the cooling air. The module 1 is mounted between cooling plate 2 and hot side pad 8. Fastener 3 joins this assembly. The entire assembly is free to travel on posts 4. When the stove surface 7 is too hot, the bimetal strip 5 forms a curve that lifts the assembly away from the stove surface 7, pressing against the force of the compression springs 9. The bimetal strip 5 is attached to the stove surface 7 with fastener 6. FIG. 6 shows the same mechanism when the stove surface is cooler. The bimetal strip has returned to its normal, flat profile, lying within a slot provided in the lower surface of the pad. Further, combinations of various overheating mechanisms can be used. A mechanism for protection is particularly useful when the generator is used in a wood or coal stove, and will be of limited beneficial use with stoves that burn a very steady temperature of fuel, such as an oil drip stove.

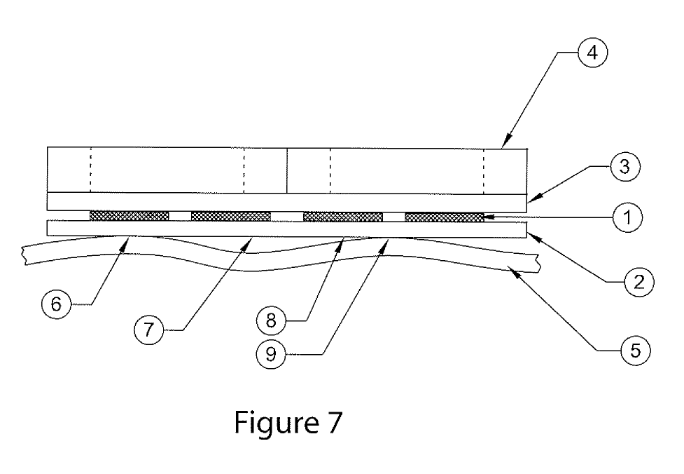

The modules within the generator can be oriented in any suitable manner. FIG. 7 shows a traditional arrangement for multiple module use in a generator. All the modules 1 are mounted between a single hot side plate 2 and a cold side plate 3, with cooling fans 4 attached to cold side plate 3. The stove surface 5 is warped from the heat it is exposed to. The result is good contact at point 6, no contact with the module at 7, and very uneven contact with the module at points 8 and 9. This will cause reduced power output from the module at point 7, and potentially destructive uneven heating in the module at point 8 and 9.

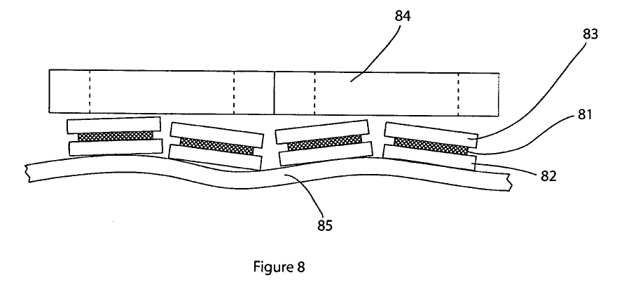

Accordingly, in a preferred embodiment, the modules are arranged in a floating arrangement. FIG. 8 shows a preferred ‘floating’ arrangement where each module is attached to its own hot side pad and cold side pad, forming a module assembly. The cooling fan(s), if used, can be attached to each module assembly, or separated from the assembly and used to cool multiple assemblies at the same time. The floating pad approach allows the module to more closely and evenly absorb heat from the uneven stove surface.

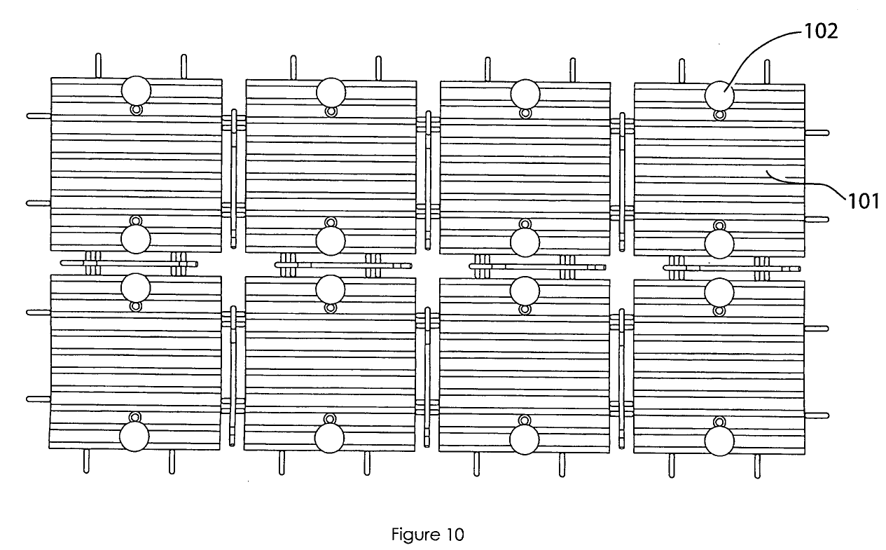

Alternatively, referring to FIGS. 10 to 12, the floating pad has also been found to be useful in the construction of a stove top generator. FIG. 10 shows an embodiment of the floating module concept where multiple modules 101 are linked together in a way that each module can optimally conform to the uneven surface of the hot side plate. When used in a horizontal arrangement, ie resting on the top of a wood stove, the force of gravity will maintain the contact between the module assemblies and the hot stove top surface. The optional spring assemblies 102 attach the module to the hot stove surface.

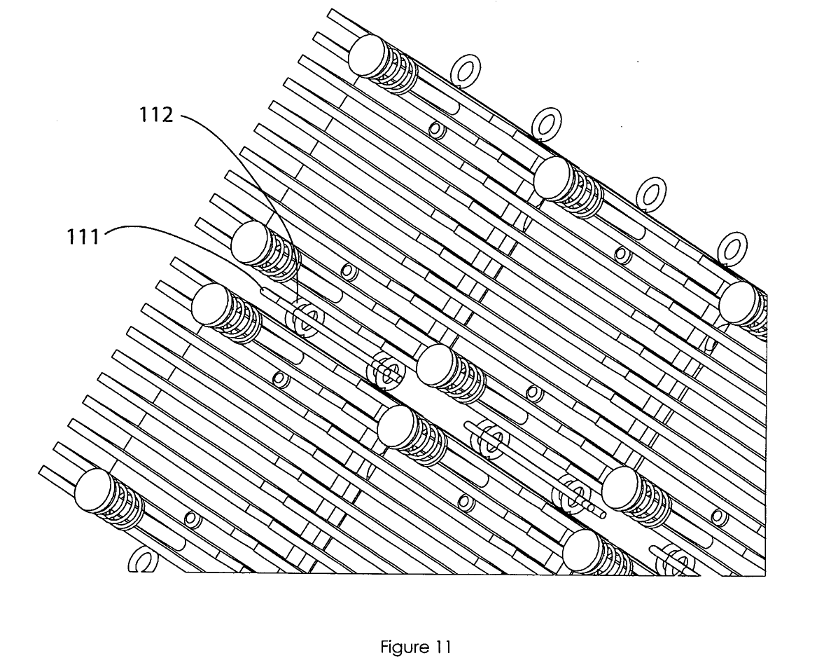

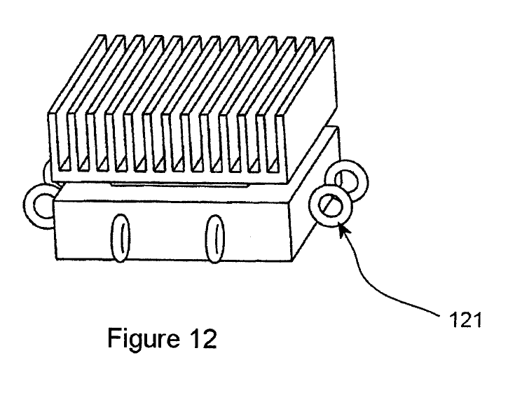

FIG. 11 shows how individual modules can be connected with linkage pins 111 through eyelets 112. The modules are loosely coupled so they can be handled as a group, and will conform to an uneven surface. FIG. 12 shows the construction of an individual unit as used in FIGS. 10 and 11. The construction is the same as in FIG. 5, with the addition of the eyelets 121 and the omission of the optional spring assemblies.

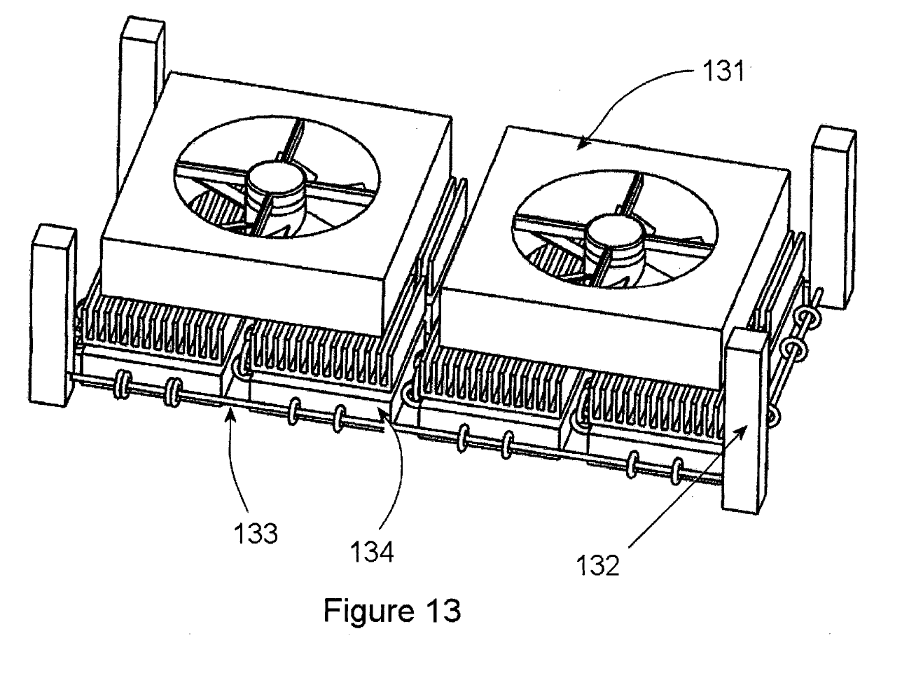

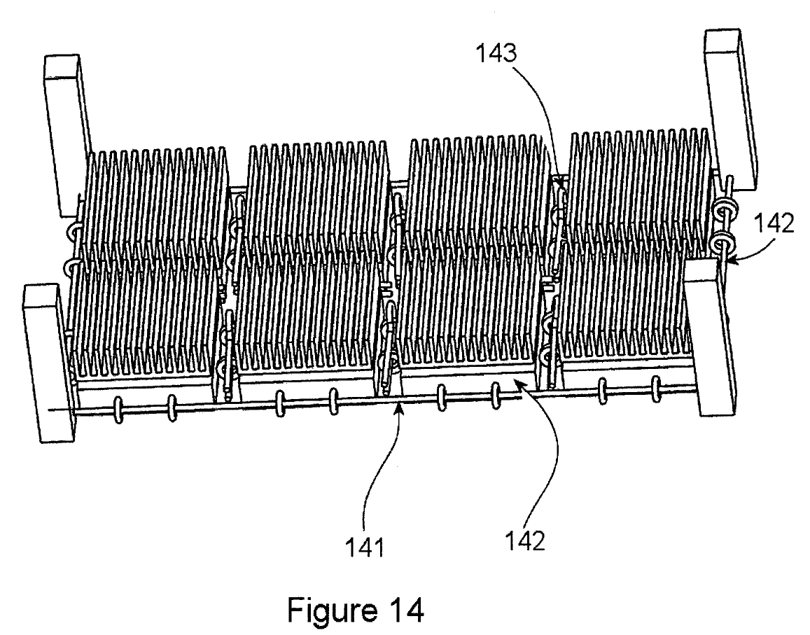

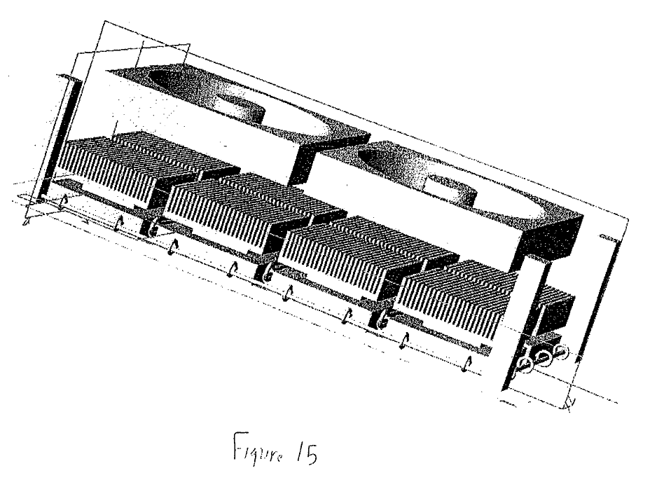

FIGS. 13 and 14 illustrate a stovetop generator with float pads in one embodiment and FIG. 15 illustrates a complete assembly of a stovetop generator with these float pads. A stove top generator is required to operate on a wide range of stoves, both new and old. The top surfaces of stoves are particularly susceptible to warping since the surface is immediately above the flame. Also, the surface was not designed with intent to maintain flatness. With sufficient travel allowed between the pads, a stove top generator may be used on a barrel stove. In this embodiment, the capacity of the generator can be easily expanded by adding more module assemblies.

FIG. 13 shows an embodiment of the assembly array in which the cold side is cooled by two fans. Any number of fans can be used. The fans 131 are supported by the frame 132. The frame also connects the support rods 133 that hold the outer sides of the modules 134.

FIG. 14 shows the same assembly as FIG. 13 with the fans removed to show the modules 141 connected by the support rods 142 and the linkage pins 143.

In either embodiment, (door mounted generator or stove-top generator) use of the floating pad adds an additional benefit with respect to field service. Separate pads for each module provide for much easier replacement of failed modules, as the failed assembly can be easily removed without affecting the other modules. Assembly of modules between the hot and cold plates requires special equipment and techniques not available to the general public so replacing a failed module is not possible. Replacing the failed assembly requires simple tools.

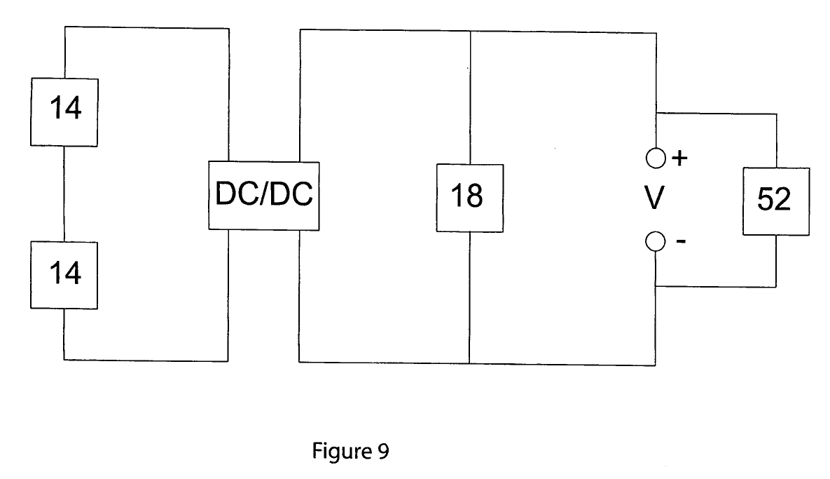

FIG. 9 illustrates a top level circuit diagram of the module circuit 50. Each module 14 generates power using a DC/DC converter. Some of that electric power is used to power the cooling fans 18 and the remainder (net power) is available to charge the battery 52. The generator will normally use the net power available to charge a battery (energy storage device). The battery will then be used to power any of a variety of devices, which may include but are not limited to lights, fans, and radios. It is also possible to directly operate devices from the generator, though this is must be carefully considered, and ideally designed for, since the output from the TE generator depends on the load. When the generator is designed to charge a known battery, then the system can be optimized to create maximum power output.

In the embodiment of FIG. 1, the generator/door combination weighs about 60 to 80 lbs. The door is mounted to the stove via a 12 inch pin to support the weight. The normal door with glass weighs approximately 22 lbs. The glass alone weighs 3 lbs. A prototype generator weighs 10 lbs. Substituting the generator for the glass gives a total weight of 29 lbs.

Electric devices may be run directly from the generator, for example lights, circulating fans, radios, or computers; devices may be charged by the generator, for example cameras, cell phones, GPS or computers, or the energy may be stored in a battery.

Although embodiments of the invention have been described with respect to wood or coal stoves, the invention can also be used in other types of stoves, such as stoves that burn a very steady temperature of fuel such as an oil drip stove.

Numerous modifications may be made without departing from the spirit and scope of the invention as defined in the appended claims.

What is claimed is:

1. In combination, a stove and a thermoelectric generator; wherein:
the stove has a heating chamber; and
the generator has a hot side plate positioned in use within the heating chamber in a direct path of the heat therefrom.

2. The combination of claim 1, wherein the generator is incorporated with a door of the stove.

3. The combination of claim 2, wherein the generator has a cold side plate positioned in use to be exposed to ambient air close to the ground.

4. The combination of claim 1, wherein the cold side plate comprises cooling fins.

5. The combination of claim 4, wherein the cooling fins are positioned to be exposed to ambient air close to the ground.

6. The combination of claim 1, wherein the generator further comprises a protective mechanism to protect the generator from overheating

7. The combination of claim 6, wherein the protective mechanism comprises a grillwork guard to prevent burning wood from resting directly on the generator mechanism.

8. The combination of claim 6, wherein the protective mechanism may be a shutter that closes to block the direct heat from the generator mechanism.

9. The combination of claim 8, wherein the shutter is controlled by a bimetal mechanism that automatically closes the shutter as the heat increases.

10. The combination of claim 6, wherein the stove is a wood or coal stove.

11. The combination of claim 2, wherein the stove is an oil drip stove.

12. The combination of claim 2, wherein a side by side arrangement for multiple modules is used.

13. The combination of claim 2, wherein the modules are arranged in a floating arrangement to more closely and evenly absorb heat from the uneven stove surface.

14. The combination of claim 2, wherein the generator further comprises cooling fans.

15. The combination of claim 14, wherein some power generated by the generator is used to power the cooling fans.

16. The combination of claim 2, further comprising an energy storage device.

17. The combination of claim 16, wherein power in the energy storage device is can be to power external devices.

18. The combination of claim 17, wherein the external devices include lights, fans or radios.

19. A stove top generator, wherein the modules are arranged in a floating arrangement to more closely and evenly absorb heat from the uneven stove surface.

20. A method of generating power using in combination, a stove and a thermo-electric generator; wherein the stove has a heating chamber, the method comprising:
positioning a hot side plate of the generator within the heating chamber of the stove in a direct path of the heat therefrom in use.
